(19) United States
(12) Patent Application Publication
(10) Pub. No.: US 2026/0366194 A1
(43) Pub. Date: Nov. 19, 2026

(54) SUSTAINED-RELEASE DEVICE, AND RUBIDIUM-POTASSIUM TITANYL PHOSPHATE CRYSTAL AND PREPARATION METHOD THEREOF

(71) Applicant: Guilin Bairay Photoelectric Technology Co., Ltd., Guilin City (CN)

(72) Inventors: Changlong Zhang, Guilin City (CN); Xiaoling He, Guilin City (CN); Zhanggui Hu, Guilin City (CN); Haitao Zhou, Guilin City (CN)

(21) Appl. No.: 19/362,370

(22) Filed: Oct. 18, 2025

(30) Foreign Application Priority Data
May 16, 2025 (CN) 202510637503.8

(51) Int. Cl. C30B 29/14; C30B 7/10; C30B 35/00

(52) U.S. Cl. CPC C30B 29/14; C30B 7/10; C30B 35/002

(57) ABSTRACT

A sustained-release device, and a rubidium-potassium titanyl phosphate (Rb:KTP) crystal and a preparation method thereof are provided. The sustained-release device includes a hollow inner tube and a hollow outer tube sleeved on the hollow inner tube; where the hollow inner tube and the hollow outer tube each have a closed structure that is provided with a sustained-release orifice at a top thereof, and the sustained-release orifice has a diameter of 0.3 mm to 3 mm.

### CROSS REFERENCE TO RELATED APPLICATION

This patent application claims the benefit and priority of Chinese Patent Application No. 202510637503.8, entitled “Sustained-release device, and rubidium-potassium titanyl phosphate crystal and preparation method thereof” filed on May 16, 2025, the disclosure of which is incorporated by reference herein in its entirety as part of the present application.

### TECHNICAL FIELD

The present disclosure belongs to the technical field of electro-optic crystals and nonlinear optical crystals, and specifically relates to a sustained-release device, and a rubidium (Rb)-potassium titanyl phosphate (KTiOPO₄, abbreviated as KTP) crystal, namely an Rb:KTiOPO₄ crystal (Rb:KTP crystal) and a preparation method thereof.

### BACKGROUND

Potassium titanyl phosphate (KTP) crystals grown by the hydrothermal method exhibit outstanding nonlinear optical and electro-optic properties. However, they suffer from problems such as small crystal dimensions, high costs, and difficulties in widespread application. Moreover, hydrothermally grown KTP crystals typically exhibit resistivity only in an order of magnitude of 10¹⁰ Ω·cm at room temperature, not meeting the requirements for electro-optic applications. The flux method (also known as the molten salt method) enables batch production of large-sized, high-quality, low-cost KTP crystals, facilitating broad utilization of their nonlinear optical properties. Nevertheless, flux-grown KTP crystals face two critical limitations: gray tracking and low resistivity (in an order of magnitude of 10⁶ Ω·cm to 10⁷ Ω·cm at room temperature), hindering their applications in electro-optical fields. Since KTP crystals decompose at high temperatures and lack a congruent eutectic point, only hydrothermal and flux methods are currently viable for KTP crystal growth.

The primary obstacle to electro-optic applications of KTP crystals is their excessively low resistivity, causing electric-field-induced damage (blackening) under external electric fields. In the KTP crystal structure, large-radius tunnels exist along the Z-axis (FIG. 4, the schematic diagram of KTP crystal structure). K⁺ vacancies migrate along these tunnels under external electric fields, rendering KTP, commonly known as a quasi-one-dimensional ionic conductor, with Z-axis resistivity approximately 3 orders of magnitude lower than those of other two directions.

Incorporating suitable impurities to block conductive tunnels along the Z-axis of the KTP crystals could suppress K⁺ vacancy migration, substantially enhancing resistivity of the KTP crystals. Rubidium (Rb), being an element of the same Group I as K, with a larger ionic radius (Rb⁺:0.152 nm vs. K⁺:0.138 nm) and similar electronegativity, is an optimal dopant.

Conventional techniques typically involve mechanically mixing solid Rb salts with other solid raw materials needed for Rb:KTP crystal growth, followed by flux or hydrothermal crystal growth to obtain the Rb:KTP crystal. However, since K⁺ and Rb⁺ form infinite solid solutions in KTP crystals, only trace amounts of uniformly distributed Rb₊ avoid excessive lattice distortion, preventing crystal cracking or cloud-like defects.

Critically, even with minimal and homogenized Rb addition for Rb:KTP crystal growth, early-stage localized Rb⁺ overdoping still occurs and causes crystal cracking or cloud-like defects. At the late stage, too large Rb⁺ depletion of the early stage without replenishment leas to insufficient doping, failing to effectively enhance resistivity. As such, the resistivity distribution throughout the crystal is non-uniform.

### SUMMARY

In view of this, an object of the present disclosure is to provide a sustained-release device, and a rubidium-potassium titanyl phosphate (Rb:KTP) crystal and a preparation method thereof. Use of the sustained-release device in preparing the Rb:KTP crystal prevents crystal cracking during preparation. The Rb:KTP crystal prepared exhibits high resistivity with uniform distribution.

To achieve the above object, the present disclosure provides the following technical solutions:

Provided is the sustained-release device, including a hollow inner tube and a hollow outer tube sleeved on the hollow inner tube; where the hollow inner tube and the hollow outer tube each have a closed structure that is provided with a sustained-release orifice at a top thereof, and the sustained-release orifice has a diameter of 0.3 mm to 3 mm.

In some embodiments, an internal space of the hollow outer tube that is not occupied by the hollow inner tube is 50% to 70% of a capacity of the hollow inner tube.

In some embodiments, the hollow outer tube has an outer diameter of 6 mm to 15 mm and a height of 5 mm to 40 mm; and the hollow outer tube and the hollow inner tube each have independently a wall thickness of 0.5 mm to 0.8 mm.

In some embodiments, the sustained-release device is in a shape including cylindrical tube, capsule, sphere, or square column.

In some embodiments, the sustained-release device is made of at least one material selected from the group consisting of gold, silver, platinum, palladium, iridium, and rhodium.

The present disclosure further provides a method for preparing an Rb: KTP crystal using the sustained-release device, including the following steps:
placing a soluble solid Rb salt into the hollow inner tube of the sustained-release device as described in above technical solutions to obtain an Rb salt-loaded sustained-release device; and
placing a crushed potassium titanyl phosphate (KTP) crystal as a nutrient, a seed crystal, a mineralizer solution, and the Rb salt-loaded sustained-release device into a closed container, and conducting crystal growth, thereby obtaining the Rb:KTP crystal, where the crystal growth is conducted by a hydrothermal process.

In some embodiments, the crystal growth is conducted at a temperature of 480 °C to 550 °C and a pressure of 140 MPa to 170 MPa for 30 days to 120 days.

In some embodiments, a solute of the mineralizer solution includes K₂HPO₄, KH₂PO₄, and H₂O₂, and the mineralizer solution has a K₂HPO₄ content of 2 mol/L to 6.5 mol/L, a KH₂PO₄ content of 0.1 mol/L to 0.5 mol/L, and an H₂O₂ content of 1 wt. % to 5 wt. %.

In some embodiments, a ratio of a mass of the crushed KTP crystal as the nutrient to a volume of the mineralizer solution is 260 g:450 mL; and a mass ratio of the soluble solid Rb salt to the crushed KTP crystal as the nutrient is 1.2:260.

The present disclosure further provides an Rb:KTP crystal prepared by the method, including a KTP crystal and Rb⁺ ions doped into the KTP crystal, where a doping amount of the Rb⁺ ions is in a range of 0.15 wt. % to 0.25 wt. % of the KTP crystal.

The present disclosure provides a sustained-release device, including a hollow inner tube and a hollow outer tube sleeved on the hollow inner tube; where the hollow inner tube and the hollow outer tube each have a closed structure that is provided with a sustained-release orifice at a top thereof, and the sustained-release orifice has a diameter of 0.3 mm to 3 mm. In the present disclosure, the mineralizer solution entering an inner layer (the hollow inner tube) of the sustained-release device through the sustained-release orifice dissolves part of the soluble solid Rb salt to form a saturated solution. This solution then diffuses outward through the orifice of the hollow inner tube into an outer layer (the hollow outer tube), resulting in diluted Rb+ion concentration. The diluted solution in the outer layer further diffuses through the orifice of the hollow outer tube into the mineralizer solution for crystal growth, resulting in further diluted Rb⁺ ion concentration. This 2-stage diffusion and dilution ensure that throughout the hydrothermal growth process of 30-120 days, the Rb⁺concentration in the mineralizer solution always remains at 0.02-0.06 mol/L. Rb⁺ ions in the mineralizer solution consumed by Rb:KTP crystal growth are replenished via continuous dissolution of the soluble solid Rb salt in the hollow inner tube. Consequently, this mechanism eliminates problems including crystal cracking, cloud-like defects, and non-uniform resistivity distribution caused by directly mixing the needed soluble solid Rb salt for doping with needed crushed KTP nutrient for the Rb:KTP crystal growth, in which case, too high Rb ion concentration after dissolving all the soluble solid Rb salt at the early stage of crystal growth results in initial Rb⁺ overdoping, while Rb⁺ ions are consumed and could not be replenished at the late stage.

The present disclosure further provides a method for preparing an Rb:KTP crystal using the sustained-release device as described in above technical solutions. In the present disclosure, during Rb⁺ ion doping, the sustained-release device containing the soluble solid Rb salt enables real-time control of Rb⁺ doping amount throughout crystal growth, instead of directly mixing of the soluble solid Rb salt with crushed crystal nutrient for KTP crystal growth (Directly mixing the soluble solid Rb salt with crushed crystal nutrient for KTP crystal growth would lead to: during the crystal growth stage, high dissolution concentration of Rb compounds at the early stage results in high doping concentration of Rb into the KTP crystals; and at the late stage, due to the mass decreases, the amount of Rb compounds doped into KTP crystals. Consequently, while the resistivity is improved at the early stage, crystal uniformity and optical quality are degraded; meanwhile, due to the reduced Rb⁺ concentration, the resistivity of KTP crystal could not be effectively improved.

By the inventive method, Rb⁺ ions are gradually released into the solution through the sustained-release orifice during the entire crystal growth cycle, ensuring uniform Rb⁺ distribution in the crystal. This enhances resistivity consistency of crystal and effectively increases production yield rate of crystal. Furthermore, KTP electro-optic devices during use generally typically require using two paired crystals, thus posing very high requirements for uniformity of the two crystals. The Rb:KTP crystals produced herein exhibit markedly-improved optical uniformity, thereby enhancing performance of KTP electro-optic devices.

The core of this method lies in the “large-ion micro-doping sustained-release” technology, the core of which lies in encapsulating the dopant soluble solid Rb salt in a sustained-release device with an orifice, to enable continuous, slow release of Rb⁺ into the mineralizer solution. This maintains a near-constant Rb⁺ concentration in the mineralizer solution, achieving: uniform Rb⁺ content (0.15 wt. % to 0.25 wt. %) throughout the KTP crystal; consistent resistivity across all KTP crystal regions; and batchwise and reproducible growth of hydrothermal Rb: KTP crystals with high uniformity and high resistivity (in an order of magnitude of 10¹³ Ω·cm).

The present disclosure further provides an Rb:KTP crystal prepared by the method. The Rb:KTP crystal provided by the present disclosure exhibits high laser damage resistance (>1 GW/cm² @ 1064 nm, 10 ns, 10 Hz, AR-coated) as well as superior gray-tracking resistance (absorption increase <1.5×10⁻⁵ cm/min at 1064 nm under 10 kW/cm² green laser induction), thus suitably serving for nonlinear laser frequency conversion. Such an Rb: KTP crystal also achieves elevated room-temperature resistivity (in an order of magnitude of 10¹³ Ω·cm), and maintains resistivity in an order of magnitude of 10¹¹ Ω·cm at 80 °C, fulfilling requirements for electro-optic device fabrication (as a key material for electro-optic modulation). Critically, under high-voltage electric fields, the crystal would not fail because of electric-field-induced damage and meets requirements for broad-temperature-range electro-optic devices.

### BRIEF DESCRIPTION OF THE DRAWINGS

To describe the technical solutions in examples of the present disclosure or in the prior art more clearly, the accompanying drawings required in the examples are briefly described below. Apparently, the accompanying drawings in the following description show merely some examples of the present disclosure, and other drawings could still be derived from these accompanying drawings by those of ordinary skill in the art without creative efforts.

FIG. 1A to FIG. 1C show cross-sectional views of the “sustained-release device” in an embodiment of the present disclosure, where 1 represents a hollow inner tube; 2 represents a hollow outer tube; and 3 represents a sustained-release orifice;

FIG. 2A to FIG. 2C show cross-sectional views of the “sustained-release device” loaded with soluble solid Rb salt in an embodiment of the present disclosure, where 1 represents a hollow inner tube; 2 represents a hollow outer tube; 3 represents a sustained-release orifice; and 4 represents a soluble solid Rb salt;

FIG. 3 shows a schematic diagram of crystal growth according to Example 1 of the present disclosure, where 5 represents seed crystal; 6 represents gold liner tube; 7 represents baffle; 8 represents mineralizer solution; 9 represents Rb₂CO₃-loaded sustained-release device; 10 represents crushed KTP crystals as nutrient; 11 represents autoclave; 12 represents crystal growth zone; and 13 represents crystal nutrient dissolution zone; and

FIG. 4 shows a schematic diagram of the KTP crystal structure described in the Background.

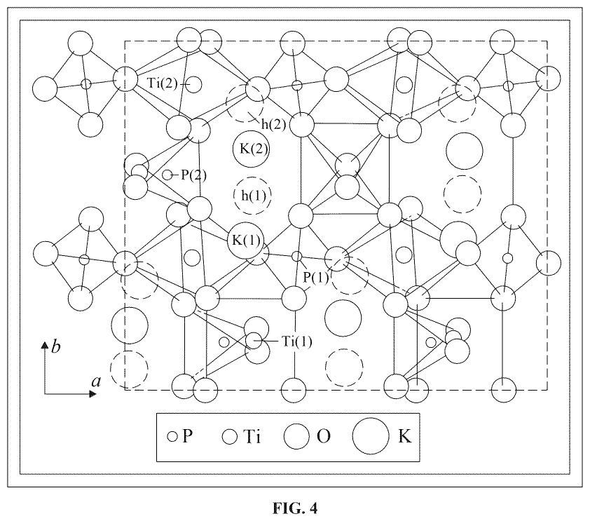

### DETAILED DESCRIPTION OF THE EMBODIMENTS

The present disclosure provides a sustained-release device, including a hollow inner tube and a hollow outer tube sleeved on the hollow inner tube; where the hollow inner tube and the hollow outer tube each have a closed structure that is provided with a sustained-release orifice at a top thereof.

In the present disclosure, unless otherwise specified, all materials and equipment used are commercially available items in the art.

In some embodiments of the present disclosure, the sustained-release orifice has a diameter ranging from 0.3-3 mm. In specific examples, it may be 0.3 mm, 0.5 mm, 0.8 mm, 1.0 mm, 1.2 mm, 1.5 mm, 1.8 mm, 2.0 mm, 2.5 mm, or 3 mm. In some embodiments, one sustained-release orifice is arranged centrally at the top of each of the hollow inner tube and the hollow outer tube.

By setting the diameter of the sustained-release orifice at 0.3-3 mm, the present disclosure modulates the release amount of the soluble solid Rb salt into the mineralizer solution per unit time, ensures uniform resistivity throughout the KTP crystal, achieves both high uniformity and resistivity, and eliminates crystal cracking/cloud-like defects. Critically, if the diameter of the orifice is too small, insufficient Rb salt is released, failing to effectively enhance resistivity; if the diameter of the orifice is too large, crystal cracks or cloud-like defects occur.

In some embodiments of the present disclosure, an internal space of the hollow outer tube that is not occupied by the hollow inner tube is 50% to 70% of the capacity of the hollow inner tube. In examples, it may specifically be 50%, 60%, or 70%.

In some embodiments of the present disclosure, the hollow outer tube has an outer diameter of 6-15 mm, specifically 6 mm, 8 mm, 10 mm, 12 mm, 13 mm, or 15 mm in examples; in some embodiments, the hollow outer tube has a height of 5-40 mm, specifically 5 mm, 10 mm, 15 mm, 18 mm, 20 mm, 25 mm, 30 mm, 35 mm, or 40 mm in examples. There is no special limitation on the outer diameter, the inner diameter, and the height of the hollow inner tube, provided that an internal space of the hollow outer tube that is not occupied by the hollow inner tube is 50% to 70% of the capacity of the hollow inner tube. In examples, the outer diameter of the hollow inner tube is preferably identical to the inner diameter of the hollow outer tube, that is to say, bottoms and walls of the hollow inner tube and the hollow outer tube are in intimate contact (i.e., sleeved together). In an example, the height of the hollow inner tube may specifically be 12 mm.

In some embodiments of the present disclosure, the hollow outer tube and the hollow inner tube each independently have a wall thickness of 0.5-0.8 mm, specifically 0.5 mm, 0.6 mm, 0.7 mm, or 0.8 mm in examples.

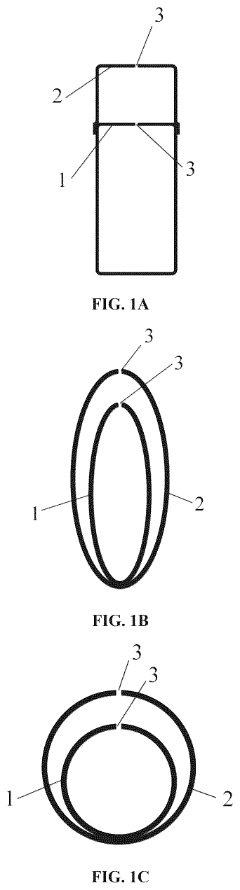

In some embodiments of the present disclosure, the sustained-release device is in a shape comprising cylindrical tube (FIG. 1A), capsule (FIG. 1B), sphere (FIG. 1C), or square column. In the present disclosure, in the sustained-release device, shapes of the hollow inner tube and the hollow outer tube may be identical or different, as long as an internal space of the hollow outer tube that is not occupied by the hollow inner tube is 50% to 70% of a capacity of the hollow inner tube, for example, the hollow inner tube being cylindrical and the hollow outer tube being square columnar. In examples of the present disclosure, the hollow inner tube and the hollow outer tube in the sustained-release device are preferably of an identical shape (FIG. 1A to FIG. 1C).

In some embodiments of the present disclosure, the sustained-release device has at least two layers (e.g., a bilayer structure shown in FIG. 1A to FIG. 1C), specifically two, three, or four layers in examples to decelerate dopant ion release.

In some embodiments, for the sustained-release device with three-or four-layer structures, the present disclosure employs: one additional hollow tube sleeved on the hollow outer tube (tri-layer sustained-release device); or two additional hollow tubes sleeved on the hollow outer tube (tetra-layer sustained-release device).

In some embodiments of the present disclosure, the sustained-release device is made of a material including: a material with high-temperature resistance (≥400 °C) and acid/alkali corrosion resistance. In some embodiments, the sustained-release device is made of a material including noble metals with high-temperature resistance and corrosion resistance; the sustained-release device is preferably made of a material including at least one of gold, silver, platinum, palladium, iridium, and rhodium.

In the present disclosure, the mineralizer solution entering an inner layer (the hollow inner tube) of the sustained-release device through the sustained-release orifice dissolves part of the soluble solid Rb salt to form a saturated solution. This solution then diffuses outward through the orifice of the hollow inner tube into an outer layer (the hollow outer tube), resulting in diluted Rb⁺ ion concentration. The diluted solution in the outer layer further diffuses through the orifice of the hollow outer tube into the mineralizer solution for crystal growth, resulting in further diluted Rb⁺ ion concentration. This 2-stage diffusion and dilution ensure that throughout the hydrothermal growth process of 30-120 days, the Rb⁺ concentration in the mineralizer solution always remains at 0.02-0.06 mol/L. Rb⁺ ions in the mineralizer solution consumed by Rb:KTP crystal growth are replenished via continuous dissolution of the soluble solid Rb salt in the hollow inner tube. Consequently, this mechanism eliminates problems including crystal cracking, cloud-like defects, and non-uniform resistivity distribution caused by directly mixing the needed soluble solid Rb salt for doping with needed crushed KTP nutrient for the Rb:KTP crystal growth, in which case, too high Rb ion concentration after dissolving all the soluble solid Rb salt at the early stage of crystal growth results in initial Rb⁺ overdoping, while Rb⁺ ions are consumed and could not be replenished at the late stage.

The present disclosure further provides a method for preparing an Rb:KTP crystal using the sustained-release device as described in above technical solutions, including the following steps:
placing a soluble solid Rb salt into the hollow inner tube of the sustained-release device as described in above technical solutions to obtain an Rb salt-loaded sustained-release device; and
placing a crushed potassium titanyl phosphate (KTP) crystal as a nutrient, a seed crystal, a mineralizer solution, and the Rb salt-loaded sustained-release device into a closed container, and conducting crystal growth, thereby obtaining the Rb:KTP crystal; where the crystal growth is conducted by a hydrothermal process.

In the present disclosure, the soluble solid Rb salt is placed into the hollow inner tube of the sustained-release device as described in above technical solutions to obtain an Rb salt-loaded sustained-release device.

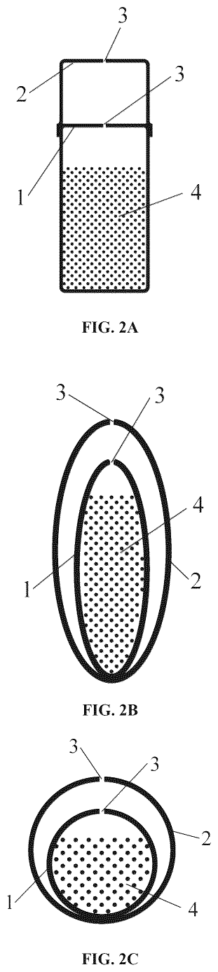

In some embodiments of the present disclosure, the soluble solid Rb salt includes at least one of Rb₂O, Rb₂CO₃, RbNO₃, RbCl, Rb₂SO₄, Rb₃PO₄, Rb₂HPO₄, and RbH₂PO₄; in some embodiments, the filling volume of the soluble solid Rb salt is 60% to 80% of the capacity of the hollow inner tube of the sustained-release device (as shown in FIG. 2A to FIG. 2C, dotted shading (i.e., 4) represents the filled soluble solid Rb salt) in the sustained-release device, specifically 60%, 70%, or 80% in examples. In some embodiments, the bulk density of Rb₂CO₃ is 2.7 g/cm³.

In the present disclosure, after obtaining the Rb salt-loaded sustained-release device, a crushed potassium titanyl phosphate (KTP) crystal as a nutrient, a seed crystal, a mineralizer solution, and the Rb salt-loaded sustained-release device are placed into a closed container, and crystal growth is conducted, thereby obtaining the Rb:KTP crystal.

In the present disclosure, there is no special limitation on a manner of the crystal growth, and conventional techniques known in the art may be adopted. In some embodiments, the closed container includes an autoclave.

In some embodiments, the crushed KTP crystal as the nutrient, the seed crystal, the mineralizer solution, and the Rb salt-loaded sustained-release device are sealed within a gold liner tube of the autoclave to prevent corrosion of the autoclave by the mineralizer solution.

In some embodiments of the present disclosure, the gold liner tube has an internal dimension of Φ38×750 mm and a wall thickness of 0.8 mm.

In some embodiments of the present disclosure, a solute of the mineralizer solution includes K₂HPO₄, KH₂PO₄, and H₂O₂; in some embodiments, the mineralizer solution has a K₂HPO₄ content of 2-6.5 mol/L, specifically 2 mol/L, 3 mol/L, 4 mol/L, 5 mol/L, 6 mol/L, or 6.5 mol/L in examples; a KH₂PO₄ content of 0.1-0.5 mol/L, specifically 0.1 mol/L, 0.2 mol/L, 0.3 mol/L, 0.4 mol/L, or 0.5 mol/L in examples; an H₂O₂ content of 1-5 wt. %, specifically 1 wt. %, 2 wt. %, 3 wt. %, 4 wt. %, or 5 wt. % in examples. In some embodiments, a ratio of a mass of the crushed KTP crystal as the nutrient to a volume of the mineralizer solution is 260 g:450 mL; in some embodiments, a mass ratio of the soluble solid Rb salt to the crushed KTP crystal as the nutrient is 1.2:260.

In some embodiments of the present disclosure, the gold liner tube of the autoclave is divided into two parts of an upper part and a lower part by a porous baffle, the upper part being a crystal growth zone; the lower part being a dissolution zone. In some embodiments, the crushed KTP crystal as the nutrient, the mineralizer solution, and the Rb₂CO₃-loaded sustained-release device are placed in the dissolution zone; the Rb₂CO₃-loaded device is positioned atop the nutrient placed in the lower part of the gold liner tube (to prevent the crushed KTP crystal as the nutrient from clogging the orifice of the sustained-release device); the seed crystal is placed in the crystal growth zone and fixed at the top of the gold liner tube.

In some embodiments of the present disclosure, the porous baffle has a porosity of 6% to 12%. There is no special limitation on a pore size of pores in the porous baffle, and a pore size well known in the art may be used.

In some embodiments of the present disclosure, the seed crystal includes a seed crystal wafer; in some embodiments, the seed crystal wafer is cut along a specific orientation; in some embodiments, the seed crystal wafer is cut along an orientation including (011), (210), (001), or (010), specifically (011) in an example.

In some embodiments of the present disclosure, the crystal growth is conducted at a temperature of 480 °C to 550 °C; in examples, the temperature in the crystal growth zone is specifically 480 °C and the temperature in the dissolution zone is 550 °C. In some embodiments, the crystal grows along the direction of (011).

In some embodiments of the present disclosure, the crystal growth is conducted for 30-120 days, specifically 30 days, 40 days, 50 days, 60 days, 70 days, 80 days, 90 days, 100 days, 110 days, or 120 days in examples; in some embodiments, the crystal growth is performed at a pressure of 140-170 MPa.

In the present disclosure, during Rb⁺ ion doping, the sustained-release device containing the soluble solid Rb salt enables real-time control of Rb⁺ doping amount throughout crystal growth, instead of directly mixing the soluble solid Rb salt with crushed crystal nutrient for KTP crystal growth (Directly mixing the soluble solid Rb salt with crushed crystal nutrient for KTP crystal growth would lead to: during the crystal growth stage, high dissolution concentration of Rb compounds at the early stage results in high doping concentration of Rb into the KTP crystal; and at the late stage, due to the mass decreases, the amount of Rb compounds doped into KTP crystals is reduced. Consequently, while the resistivity is improved at the early stage, crystal uniformity and optical quality are degraded; meanwhile, due to the reduced Rb⁺ concentration, the resistivity of KTP crystal could not be effectively improved.

By the inventive method, Rb⁺ ions are gradually released into the solution through the sustained-release orifice during the entire crystal growth cycle, ensuring uniform Rb⁺ distribution in the crystal. This enhances resistivity consistency of crystal and effectively increases production yield rate of crystal. Furthermore, KTP electro-optic devices during use generally require using two paired crystals, thus posing very high requirements for uniformity of the two crystals. The Rb: KTP crystals produced herein exhibit markedly-improved optical uniformity, thereby enhancing performance of KTP electro-optic devices.

The present disclosure proposes “large-ion micro-doping sustained-release” technology, the core of which lies in encapsulating the dopant soluble solid Rb salt in a sustained-release device with an orifice, to enable continuous, slow release of Rb⁺ into the mineralizer solution. This maintains a near-constant Rb⁺ concentration in the mineralizer solution, achieving: uniform Rb⁺ content (0.15 wt. % to 0.25 wt. %) throughout the KTP crystal; consistent resistivity across all KTP crystal regions; and batchwise and reproducible growth of hydrothermal Rb:KTP crystals with high uniformity and high resistivity (in an order of magnitude of 10¹³ Ω·cm).

The present disclosure further provides an Rb:KTP crystal prepared by the method as descried in above technical solutions, including a KTP crystal and Rb⁺ ions doped into the KTP crystal.

In some embodiments of the present disclosure, a doping amount of Rb⁺ is in a range of 0.15-0.25 wt. % of the KTP crystal, specifically 0.15%, 0.2%, or 0.25% in examples.

The Rb:KTP crystal provided by the present disclosure exhibits high laser damage resistance (>1 GW/cm² @ 1064 nm, 10 ns, 10 Hz, AR-coated) as well as superior gray-tracking resistance (absorption increase <1.5×10⁻⁵ cm/min at 1064 nm under 10 kW/cm² green laser induction), thus suitably serving for nonlinear laser frequency conversion. Such an Rb:KTP crystal also achieves elevated room-temperature resistivity (in an order of magnitude of 10¹³ Ω·cm), and maintains resistivity in an order of magnitude of 10¹¹ Ω·cm at 80 °C, fulfilling requirements for electro-optic device fabrication (as a key material for electro-optic modulation). Critically, under high-voltage electric fields, the crystal would not fail because of electric-field-induced damage and meets requirements for broad-temperature-range electro-optic devices.

In order to further illustrate the present disclosure, the sustained-release device, and the Rb:KTP crystal and the preparation method thereof provided by the present disclosure are described in detail below in conjunction with the accompanying drawings and examples, but the accompanying drawings and the examples should not be construed as limiting the scope of the present disclosure.

### Example 1

A “sustained-release device” with a structure shown in FIG. 1A was employed; this device was fabricated from gold and composed of a hollow inner tube 1 and a hollow outer tube 2 sleeved on it (i.e., a bilayer structure of the hollow inner tube and the hollow outer tube). Both tubes were closed cylinders, each with a sustained-release orifice 3 at the top.

The hollow inner tube had an outer diameter of 8 mm (intimately contacting the inner wall of the hollow outer tube, that was to say, the inner diameter of the hollow outer tube was 8 mm); both the hollow outer tube and the hollow inner tube had a wall thickness of 0.6 mm; the hollow inner tube had a height of 12 mm and the hollow outer tube had a height of 18 mm; the hollow outer tube and the hollow inner tube each are provided with one orifice having a diameter of 1.5 mm at the top center.

Solid Rb₂CO₃ (1.2 g, bulk density of Rb₂CO₃: 2.7g/cm³ ) was placed into the hollow inner tube of the sustained-release device, obtaining an Rb₂CO₃-loaded sustained-release device, where the volume of the rubidium carbonate occupied 70% of the capacity of the inner tube.

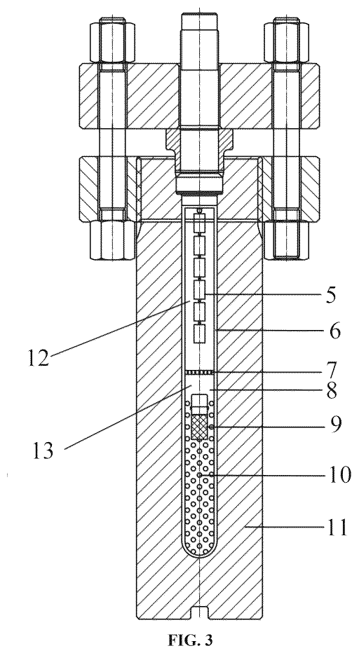

As shown in FIGS. 3, 260 g of a crushed potassium titanyl phosphate (KTP) crystal 10 as a nutrient, a seed crystal 5, 450 mL of a mineralizer solution 8 (composed of 2 mol/L K₂HPO₄+0.1 mol/L KH₂PO₄+1 wt. % H₂O₂), and the Rb₂CO₃-loaded sustained-release device 9 were sealed in a gold liner tube 6 (having an internal dimension of Φ38×750 mm; and a wall thickness of 0.8 mm) of an autoclave 11 (preventing corrosion to the autoclave by the mineralizer). Hydrothermal crystal growth was conducted to obtain an Rb:KTP crystal.

A porous baffle 7 divided the gold liner tube into two parts of an upper part and a lower part, i.e., the upper part being a crystal growth zone 12, and the lower part being a dissolution zone 13. 260 g of the crushed KTP crystal 10 as the nutrient, 450 mL of the mineralizer solution 8, and the Rb₂CO₃-loaded sustained-release device 9 were placed in the dissolution zone 13; the Rb₂CO₃-loaded sustained-release device 9 was positioned atop the nutrient (to prevent the crushed KTP crystal as the nutrient from clogging the orifice of the sustained-release device) which had been placed in the lower part of the gold liner tube 6. The seed crystal (011—cut orientation) was placed in the crystal growth zone 12 and fixed at the top of the gold liner tube.

The temperature in the dissolution zone 13 was 550 °C and the temperature in the crystal growth zone 12 was 480 °C. Owing to crystal anisotropy, directional crystal growth was needed to control rate and quality of the crystal growth; in this example, crystal grew along the 011 orientation at a work pressure of 140-170 MPa for 30 days.

### Performance Testing

The Rb:KTP crystal grown in Example 1 was cut along the (001) plane into 1 mm-thick wafers for resistivity measurement.

Electrodes having a diameter of 3 mm were used for testing, at a test temperature of 25 °C, and test points was at an interval of 5 mm. Results show all wafers exhibit resistivity in an order of magnitude of 10¹³ Ω·cm, confirming uniform resistivity distribution.

This example resolved non-uniform Rb⁺ doping-induced resistivity distribution in KTP crystals, eliminating electric-field-induced damage while meeting optical compensation requirements of two crystals in use of paired KTP electro-optic devices; it effectively enhanced both production yield and performance of KTP electro-optic devices.

Although the above embodiments have described the present disclosure in detail, they are only a part of, not all of, the embodiments of the present disclosure. Other embodiments may also be obtained by persons based on the embodiments without creative efforts, and all of these embodiments shall fall within the scope of the present disclosure.

1. A method for preparing a rubidium-potassium titanyl phosphate (Rb: KTP) crystal using a sustained-release device, wherein the sustained-release device comprises a hollow inner tube and a hollow outer tube sleeved over the hollow inner tube; the hollow inner tube and the hollow outer tube each have a closed structure that is provided with a sustained-release orifice at a top of the closed structure; and the sustained-release orifice has a diameter of 0.3 mm to 3 mm; and
the method comprises:
placing a soluble solid Rb salt into the hollow inner tube of the sustained-release device to obtain an Rb salt-loaded sustained-release device; and
placing a crushed potassium titanyl phosphate (KTP) crystal as a nutrient, a seed crystal, a mineralizer solution, and the Rb salt-loaded sustained-release device into a closed container, and conducting crystal growth, to obtain the Rb:KTP crystal; wherein the crystal growth is conducted by a hydrothermal process.

2. The method as claimed in claim 1, wherein an internal space of the hollow outer tube that is not occupied by the hollow inner tube is 50% to 70% of a capacity of the hollow inner tube.

3. The method as claimed in claim 1 or 2, wherein the hollow outer tube has an outer diameter of 6 mm to 15 mm and a height of 5 mm to 40 mm; and the hollow outer tube and the hollow inner tube each independently have a wall thickness of 0.5 mm to 0.8 mm.

4. The method as claimed in claim 1, wherein the sustained-release device is in a shape comprising cylindrical tube, capsule, sphere, or square column.

5. The method as claimed in claim 1, 2, or 4, wherein the sustained-release device is made of a material comprising at least one selected from the group consisting of gold, silver, platinum, palladium, iridium, and rhodium.

6. The method as claimed in claim 1, wherein the crystal growth is conducted at a temperature of 480 °C to 550 °C and a pressure of 140 MPa to 170 MPa for 30 days to 120 days.

7. The method as claimed in claim 1 or 6, wherein a solute of the mineralizer solution comprises K₂HPO₄, KH₂PO₄, and H₂O₂; and
the mineralizer solution has a K₂HPO₄ content of 2 mol/L to 6.5 mol/L, a KH₂PO₄ content of 0.1 mol/L to 0.5 mol/L, and an H₂O₂ content of 1 wt. % to 5 wt. %.

8. The method as claimed in claim 7, wherein a ratio of a mass of the crushed KTP crystal as the nutrient to a volume of the mineralizer solution is 260 g:450 ml; and a mass ratio of the soluble solid Rb salt to the crushed KTP crystal as the nutrient is 1.2:260.

9. An Rb:KTP crystal prepared by the method as claimed in any one of claims 1 to 8, comprising a KTP crystal and Rb+ions doped into the KTP crystal, wherein a doping amount of the Rb⁺ ions is in a range of 0.15 wt. % to 0.25 wt. % of the KTP crystal.
